(19) United States
(12) Patent Application Publication
(10) Pub. No.: US 2008/0122501 A1
(43) Pub. Date: May 29, 2008

(54) CLOCK TIMING ADJUSTING METHOD AND SEMICONDUCTOR INTEGRATED CIRCUIT

(76) Inventors: Maki Narusawa, Kanagawa (JP); Hiroki Shinde, Kanagawa (JP)

Correspondence Address: MCDERMOTT WILL & EMERY LLP, 600 13TH STREET, NW, WASHINGTON, DC, 20005-3096, US

(21) Appl. No.: 11/945,508

(22) Filed: Nov. 27, 2007

(30) Foreign Application Priority Data
Nov. 29, 2006 (JP) 2006-321231

(51) Int. Cl. H03L 7/06

(52) U.S. Cl. 327/144

(57) ABSTRACT

There is provided with a clock timing adjusting method for adjusting the difference of clock timings among a plurality of clock domains in a semiconductor integrated circuit which includes a clock generation portion capable of supplying a plurality of clocks with different phases, a plurality of clock domains for supplying clocks supplied from the clock generation portion to corresponding flip-flop groups, respectively, and a logic circuit portion having the flip-flop groups. In the clock timing adjusting method, a latency of each of the plurality of clock domains is extracted, then the phases of clocks supplied to the clock domains are determined among the plurality of clocks generated from the clock generation portion based on the extracted latencies, and the number of clock buffers is determined in order to adjust a latency difference of the plurality of clock domains which can not be adjusted by the determined clocks.

### BACKGROUND OF THE INVENTION

1. Field of the invention

The present invention relates to a clock timing adjusting method for adjusting clock timings among a plurality of clock domains provided at a semiconductor integrated circuit and relates to the semiconductor integrated circuit.

2. Description of the related art

FIG. 10 is a diagram showing a semiconductor integrated circuit of a related art. The semiconductor integrated circuit shown in FIG. 10 includes a clock generation portion 101 and a logical circuit portion 106. FIG. 11 is a block diagram showing the clock generation portion 101. The clock generation portion 101 includes a phase/frequency detector (PFD) 108, a charge pump 109, a low-pass filter (LPF) 110, a voltage controlled oscillator (VCO) 112 and a frequency dividing circuit (1/N) 113.

As shown in FIG. 10, the logical circuit portion 106 includes a clock distribution circuits (clock domains) 102, 103 and flip-flop groups 104, 105. In the logical circuit portion 106, since data is transmitted and received between the flip-flop group 104 and the flip-flop group 105, the clock domains 102, 103 are designed in a manner that clocks are synchronized therebetween (see a patent document 1).

However, since the positional layout and the circuit configuration are not same between the clock domains 102, 103, a delay vale (hereinafter referred to a latency) to a flip-flop of the final stage seen from the clock generation portion 101 side differs between the clock domains (between the clock domains 102, 103 in the example of FIG. 10). Thus, a clock buffer 107 for adjusting a delay value is provided at the clock domain having a smaller latency (the clock domain 102 in FIG. 10) so as to eliminate the difference of the latency between the clock domains.

Patent Document 1: JP-A-9-269847

However, the semiconductor integrated circuit shown in FIG. 10 is required to dispose many clock buffers merely in order to adjust the delay. Further, the timing design of the clock domain may depart largely from the ideal equivalent-stage design depending on the disposing configuration of the clock buffer 107. In this case, not only the consumption current of the clock domain increases but also the variation range of the latency increases due to causes such as the temperature change, the change of the power source voltage, the change of the variation of Vt, whereby the variations of the latencies between the clock domains increases. As a result, it becomes difficult to secure the timing guarantee.

### SUMMARY OF THE INVENTION

An object of the invention is to provide a clock timing adjusting method which can easily adjust the timings between a plurality of clock domains provided in a semiconductor integrated circuit and also provide the semiconductor integrated circuit.

The invention provides a clock timing adjusting method for adjusting a difference of clock timings among a plurality of clock domains in a semiconductor integrated circuit which includes a clock generation portion capable of supplying a plurality of clocks with different phases, a plurality of clock domains which is supplied with clocks from the clock generation portion and supplies the clocks thus supplied to corresponding flip-flop groups, respectively, and a logic circuit portion having the flip-flop groups, the method including:
a latency extracting step of extracting a latency of each of the plurality of clock domains;
a rough adjusting step of determining phases of clocks supplied to the clock domains among the plurality of clocks generated from the clock generation portion, based on the extracted latencies; and
a fine adjusting step of determining a number of clock buffers in order to adjust a latency difference of the plurality of clock domains which can not be adjusted by the clocks determined in the rough adjusting step.

The aforesaid clock timing adjusting method further includes a clock timing changing step of shifting operating timing of the clocks of the phases determined in the rough adjusting step, at each of the clock domains, in accordance with an error state at a time where the clocks of the phases determined in the rough adjusting step are supplied to the plurality of clock domains.

The invention provides a semiconductor integrated circuit, including:
a clock generation portion which is capable of supplying a plurality of clocks with different phases;
a plurality of clock domains which is supplied with clocks from the clock generation portion and supplies the clocks thus supplied to corresponding flip-flop groups, respectively; and
a logic circuit portion having the flip-flop groups, wherein
phases of the clocks supplied to the plurality of clock domains from the clock generation portion are determined based on latencies of the clock domains, and
at least one of the plurality of clock domains includes a clock buffer for adjusting a difference of the latencies of the plurality of clock domains which can not be adjusted by the clocks of the phases thus determined.

In the aforesaid semiconductor integrated circuit, the operating timing of the clocks of the phases thus determined is shifted at each of the clock domains in accordance with an error state at a time where the clocks of the phases thus determined are supplied to the plurality of clock domains.

In the aforesaid semiconductor integrated circuit, the logic circuit portion includes frequency dividing circuits provided at pre-stages of the plurality of clock domains, respectively.

In the aforesaid semiconductor integrated circuit, the clock generating portion includes a selector which selects and outputs one of the plurality of clocks with different phases.

In the aforesaid semiconductor integrated circuit, the clock generating portion includes a selector which selects one of the plurality of clocks with different phases and feeds the selected one clock back into the clock generating portion.

According to the semiconductor integrated circuit and the clock timing adjusting method of the invention, the timing adjustment can be facilitated among the plurality of clock domains provided at the semiconductor integrated circuit. As a result, the number of the clock buffers used for the timing adjustment can be reduced. Thus, it becomes easy to design so as to be small in a consumption current value and have a small area. Further, the variance of the delay value caused by the temperature change, the power supply voltage change and the variance of Vt etc. can be suppressed and the timing design can be facilitated.

### BRIEF DESCRIPTION OF THE DRAWINGS

FIG. 1 is a diagram showing a semiconductor integrated circuit according to the first embodiment.

FIG. 2 is a block diagram showing a multi-phase clock generation portion.

FIG. 3 is a timing chart showing the change of multi-phase clocks φ0-φ4.

FIG. 4 is a flowchart showing a design processing procedure for determining the distribution of the multi-phase clocks according to the first embodiment.

FIG. 5 is a flowchart showing a design processing procedure for determining the distribution of the multi-phase clocks according to the second embodiment.

FIG. 6 is a diagram showing a semiconductor integrated circuit according to the third embodiment.

FIG. 7 is a diagram showing a semiconductor integrated circuit according to the fourth embodiment.

FIG. 8 is a block diagram showing a multi-phase clock generation portion of the fifth embodiment.

FIG. 9 is a block diagram showing a multi-phase clock generation portion of the sixth embodiment.

FIG. 10 is a diagram showing a semiconductor integrated circuit of a related art.

FIG. 11 is a block diagram showing a clock generation portion.

### DESCRIPTION OF THE PREFERRED EMBODIMENTS

A semiconductor integrated circuit and a clock timing adjusting method according to the invention will be explained with reference to drawings.

### First Embodiment

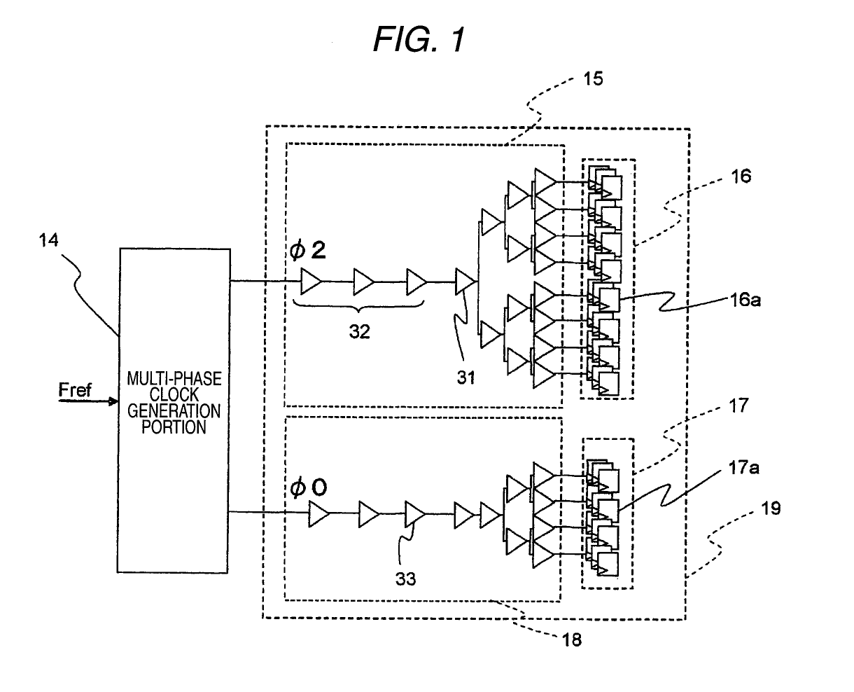

FIG. 1 is a diagram showing the semiconductor integrated circuit according to the first embodiment. As shown in FIG. 1, the semiconductor integrated circuit according to the first embodiment includes a multi-phase clock generation portion 14 and a logic circuit portion 19 disposed on the same board. A plurality of clock domains 15, 18 each configured in a tree structure are disposed in the logic circuit portion 19. The clock domains 15, 18 distribute clocks to flip-flop groups 16,17, respectively. In the first embodiment, although the number of the clock domains (clock distribution circuits) is two, the number may be arbitrary.

The flip-flop groups 16, 17 are provided with many flip-flops 16a, 17a, respectively. The clock domain 15 is provided with a plurality of clock buffers 31 and clock buffers 32 for fine adjustment. The clock domain 18 is provided with a plurality of clock buffers 33.

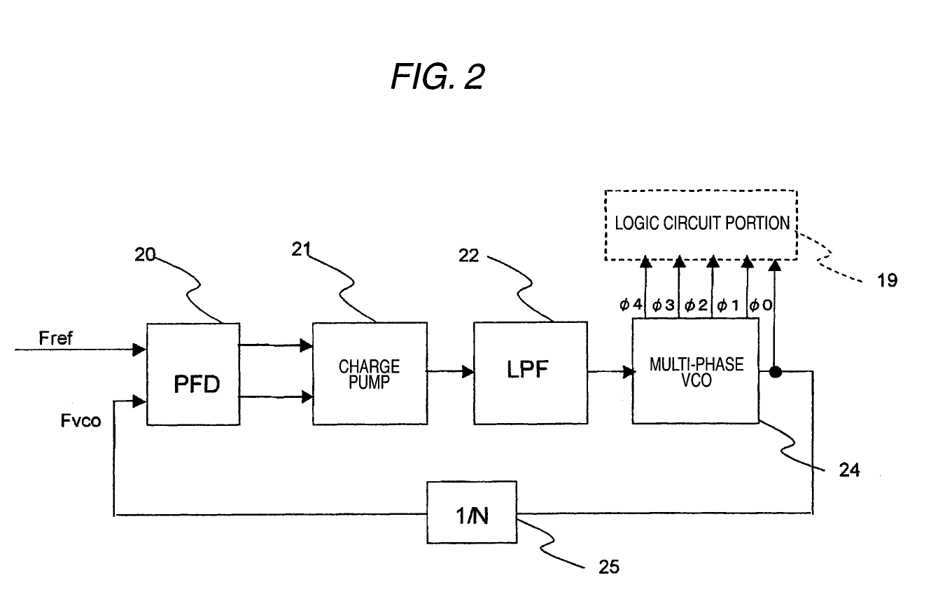

FIG. 2 is a block diagram showing the multi-phase clock generation portion 14. The multi-phase clock generation portion 14 is a multi-phase PLL which includes a phase/frequency detector (PFD) 20, a charge pump 21, a low-pass filter (LPF), a multi-phase voltage controlled oscillator (multi-phase VCO) 24 and a frequency dividing circuit (1/N) 25.

The multi-phase VCO 24 is a VCO configured by a ring oscillator in which inverters are coupled in a ring manner or a VCO in which a plurality of ring oscillators are tightly coupled. Multi-phase clocks φ0-φ4 outputted from the multi-phase VCO 24 are taken out from the inverter ring and outputted to a logic circuit portion 19 in a state that the output period T of the clock is equally divided into five.

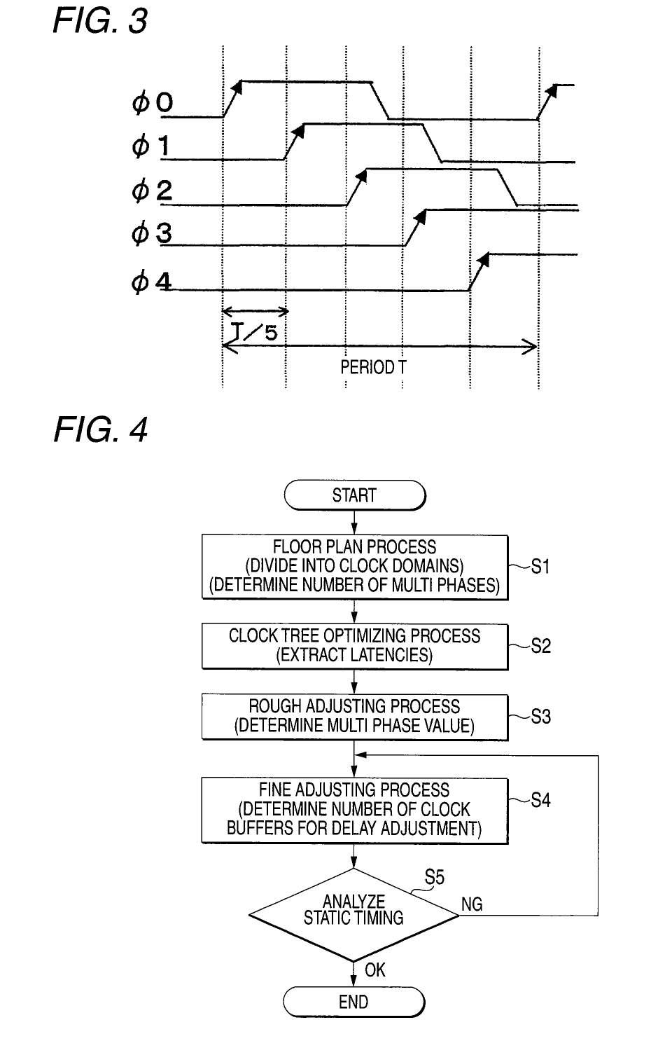

FIG. 3 is a timing chart showing the change of the multi-phase clocks φ0-φ4. The ring oscillator configured by the inverter ring oscillates in a manner that the inverters are mutually phase-coupled. Thus, the variations among the phases of the multi-phase clocks (φ0-φ4) taken out from the inverter ring are hardly influenced by the temperature change, the voltage change and the change of Vt. As a result, the phase resolution (phase DNL) of high accuracy can be guaranteed.

The minimum phase width ΔTd of the multi-phase clocks outputted from the multi-phase VCO 24 is represented by the following expression (1) supposing that the period of the clocks is T and the total number of the inverters (total number of the multi-phase outputs) within the VCO is N (N is a natural number.

ΔTd=T/N (1)

As described above, the logic circuit portion 19 is provided with the two clock domains, that is, the clock domain 15 and the clock domain 18. The clock domains 15, 18 are required to be synchronized in order to transmit and receive data between the flip-flop group 16 of the clock domain 15 and the flip-flop group 17 of the clock domain 18. However, the positional layout and the circuit configuration are not same between the clock domains 15, 18. Thus, as to a delay vale (hereinafter referred to a latency) to a flip-flop of the final stage seen from the clock generation portion 14 side, there arises a difference Td of the latency between the clock domains 15 and 18.

In the related art, as described above, a clock buffer corresponding to the latency difference Td is provided at the clock domain having a smaller latency thereby to synchronize between the clock domains. In contrast, according to the embodiment, the latency is adjusted according to procedures shown in FIG. 4.

FIG. 4 is a flowchart showing a design processing procedure (latency adjusting method) for determining the distribution of the multi-phase clocks according to the first embodiment. In the case of adjusting the latency, firstly, in a floor plan process (step S1), the logic circuit portion is divided into a plurality of the clock domains and the number of the multi phases is provisionally decided. Thereafter, in a clock tree optimizing process (step S2), the latencies are extracted. Then, in a rough adjusting process (step S3), a rough adjusting value Td1 is determined based on the extraction result of the latencies. In the rough adjusting process (step S3), the rough adjusting value Td1 is determined to a value which is obtained by shifting the clock source by M-phase from the reference phase φ0 of the multi-phase clock. Further, in a fine adjusting process (step S4), a fine adjusting value Td2 is determined provisionally. The rough adjusting value Td1 and the fine adjusting value Td2 are obtained by the following expressions (2) and (3).

Td/ΔTd=M+surplus Td2 (M is a natural number) (2)

Td1=M·(T/N)=M·ΔTd (3)

Finally, by using the clock buffer and the delay of wiring, the fine adjusting value Td2 thus determined provisionally is adjusted until each of a set up error representing constraint violation that the arrival of a signal is too late and a hold error representing constraint violation that the arrival of a signal is too fast converges, thereby to synchronize the timings. That is, the static timing analysis is performed and the result thereof is discriminated (step S5). When the result of the static timing analysis is good, the processing terminates. In contrast, when the result is not good, the process returns to step S4 and the fine adjusting value Td2 is changed.

Next, a concrete example of the latency adjustment will be explained by using simple values. That is, it is supposed that the clock period T is 10 ns, the number N of the multi-phases is 5 (multi-phase clocks φ0-φ4), the latency difference Td is 5.5 ns, and the average adjustment resolution of one clock buffer is 50 ps.

According to the expressions (1), (2) and (3), minimum phase width ΔTd, the natural number M, the rough adjusting value Td1 and the fine adjusting value Td2 are represented as follows.

ΔTd=2 ns, M =2, Td1=4 ns, and Td2=1.5 ns.

According to the latency adjusting method of the related art, it is required to provide 110 clock buffers for the delay adjustment. In contrast, according to the latency adjusting method of the embodiment, it is required to provide only 30 clock buffers by changing the output positions of the multi-phase clocks to the clock φ2 which is shifted by two phases (M=2) from the clock φ0.

Since the clock buffer is likely influenced by the temperature, the power supply voltage and the variation of Vt, the variance value of the latency to be guaranteed increases in proportional to the number of the clock buffers. Supposing that the delay variance of one block buffer is ΔT, in the case where 110 clock buffer are provided in accordance with the latency adjusting method of the related art, the timing is required to be designed in view of the variance value of 110·ΔT. In contrast, in the case where the timing is designed by using the multi-phase clocks according to the latency adjusting method of the embodiment, since the outputs of the phase clocks are tightly coupled due to the inverter ring, the relative accuracy between the clockφ0 and the clock φ2 is negligibly small as compared with the variance of the clock buffers. Since the number of the clock buffers provided according to the latency adjusting method of the embodiment is small, that is, 30, the delay variance is suppressed to ⅓ or less as compared with the relate art and so the timing design can be facilitated.

As explained above, according to the semiconductor integrated circuit and the latency adjusting method of the first embodiment, the number of the clock buffers used for the timing adjustment can be reduced. As a result, it becomes easy to design so as to be small in a consumption current value and have a small area. Further, the variance of the delay value caused by the temperature change, the power supply voltage and the variance of Vt etc. can be suppressed and the timing design can be facilitated.

### Second Embodiment

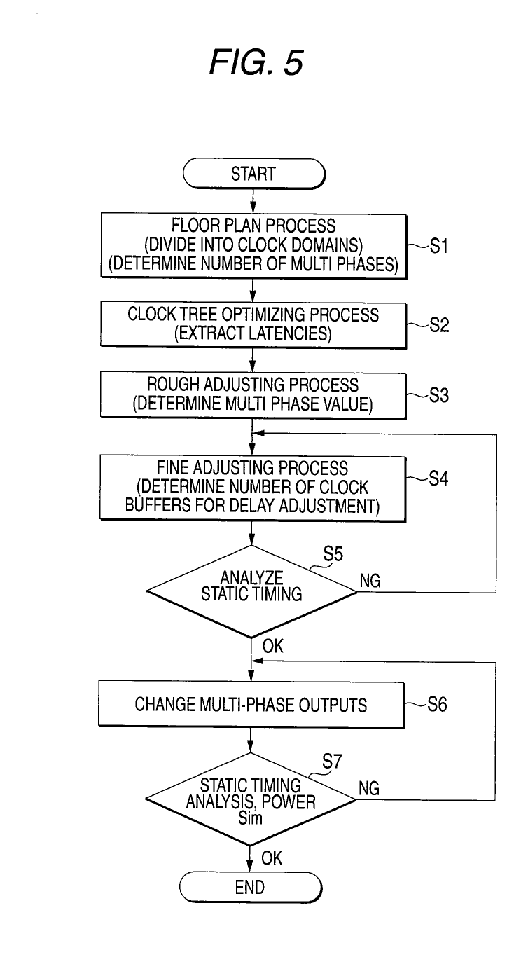

FIG. 5 is a flowchart showing a design processing procedure (latency adjusting method) for determining the distribution of the multi-phase clocks according to the second embodiment. In the figure, processes identical to those of the first embodiment are referred to by the common symbols, with explanation thereof being omitted.

In the second embodiment, when there is a margin in the worst values of the set up error and the hold error at the timing among the clock domains adjusted so that the latency becomes zero by using the outputs of the multi-phase clocks, the taken-out output position from the multi-phase clock generation portion 14 as to each of the clock domains is changed to shift the latency in a range that the margin does not become zero.

That is, after the fine adjusting value Td2 is adjusted, when it is determined that the result of the static timing analysis is good in step S5, the operation timings of the multi-phase clocks are changed so long as the margin in the worst values of the set up error and the hold error does not become zero (step S6). Then, a static timing analysis is performed and the result thereof is discriminated (step S7). When the discrimination result of the step S7 is good, the processing terminates. In contrast, when the result is not good, the process returns to step S6 and the output positions of the multi-phase clocks are changed.

According to the semiconductor circuit of the second embodiment, the clock operation timing can be shifted at every clock domain and so a peak electric power at the time of the operation can be reduced. Further, since only the output source of the multi-phase clock is changed, the delay value on the layout does not change and so it is not necessary to perform the layout again. Furthermore, since the reduction of the peak power results in the reduction of a load as to a power supply IC to be connected and also results in the reduction of the IR drop (voltage drop due to the resistance component of the wiring) within an LSI, the design margin can be reduced.

Further, such the processing can be applied to the macro timing adjustment such as between the analog and the logic, a memory and a logic, the analog and the analog. The reduction of a peak value of the power supply voltage drop also contributes to the characteristic improvement such as the reduction of a PSRR (power supply rejection ratio) or a bit error rate.

### Third Embodiment

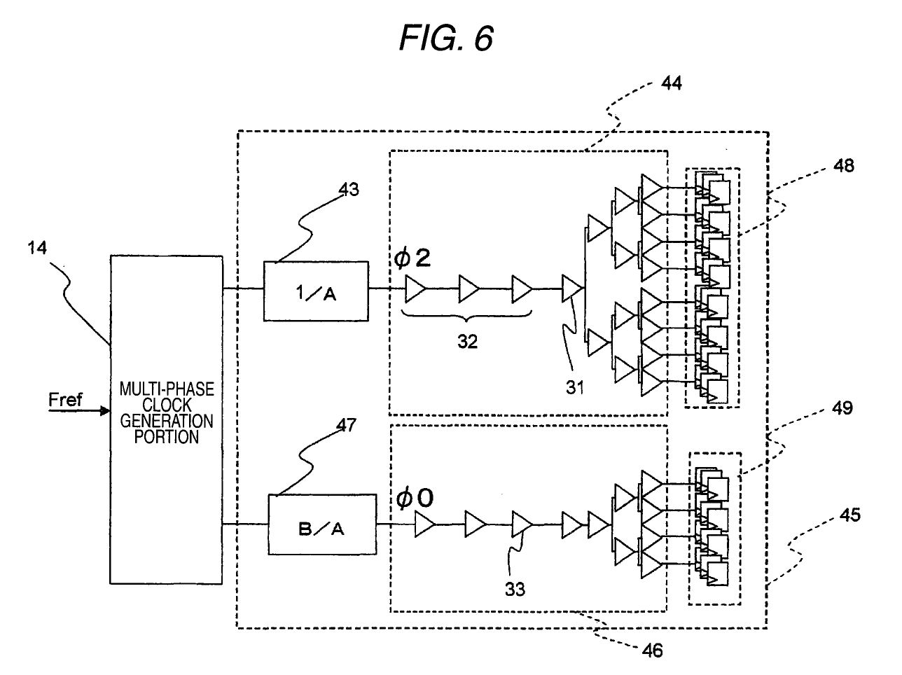

FIG. 6 is a diagram showing a semiconductor integrated circuit according to the third embodiment. In the figure, constituent elements identical to those of the first embodiment are referred to by the common symbols, with explanation thereof being omitted. The semiconductor integrated circuit according to the third embodiment includes a multi-phase clock generation portion 14 and a logic circuit portion 45 disposed on the same board. A plurality of clock domains 44, 46 each configured in a tree structure are disposed in the logic circuit portion 45. The clock domains 44, 46 distribute clocks to flip-flop groups 48, 49, respectively. The potion 45 further includes frequency dividing circuits 43, 47.

The frequency dividing circuit 43 is disposed between the multi-phase clock generation portion 14 and the clock domain 44 and divides the frequency of clocks supplied to the clock domain 44 to 1/A. The frequency dividing circuit 47 is disposed between the multi-phase clock generation portion 14 and the clock domain 46 and divides the frequency of clocks supplied to the clock domain 46 to B/A.

The frequency of the clocks distributed to the clock domain 46 is an integer number of times (B times) as large as the frequency of the clocks distributed to the clock domain 44. The clocks outputted from the multi-phase clock generation portion 14 having the same frequency and different phases are supplied to the clock domains 44, 46 via the frequency dividing circuits 43, 47, respectively.

As explained above, according to the semiconductor integrated circuit of the third embodiment, in the case of adjusting the clock timings at the time of transmission/reception of data among the different kinds of the clock domains having the relation of the integer number of times as to the clock frequencies, it is merely required to set the minimum number of the clock buffers, the timing design can be facilitated.

### Fourth Embodiment

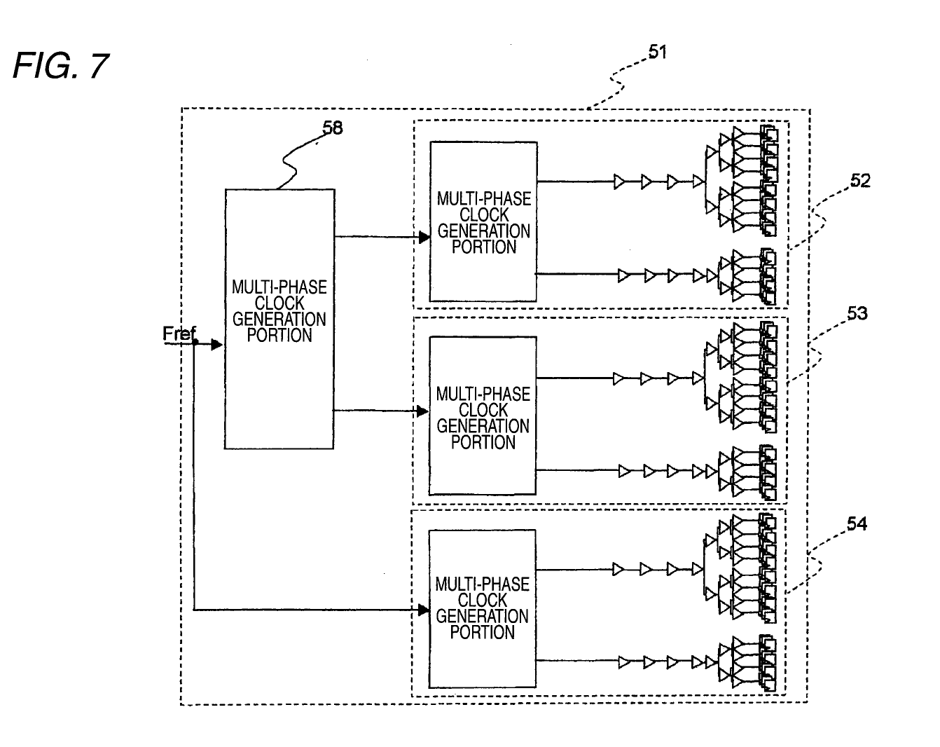

FIG. 7 is a diagram showing a semiconductor integrated circuit according to the fourth embodiment. In the semiconductor integrated circuit according to the fourth embodiment, a multi-phase clock generation portion, clock domains and flip-flop groups are configured as a single element and a plurality of elements are provided in a manner that each of the elements is configured in a tree structure. To be concrete, the semiconductor integrated circuit according to the fourth embodiment shown in FIG. 7 includes a multi-phase clock generation portion 58 and a plurality of the elements 52, 53, 54. Each of the elements 52, 53, 54 includes the multi-phase clock generation portion, the clock domains and the flip-flop groups.

Multi-phase clock generation portions 52a, 53a receive clocks having the same frequency as that of a reference clock Fref and different phases which are outputted from the multi-phase clock generation portion 58, respectively. The reference clock Fref is directly applied to a multi-phase clock generation portion 54a.

According to the semiconductor integrated circuit of the fourth embodiment, since the output of the multi-phase clock is hierarchized, a plurality of the clock domains divided duet to the constraint of the function and the area can be synchronized easily.

### Fifth Embodiment

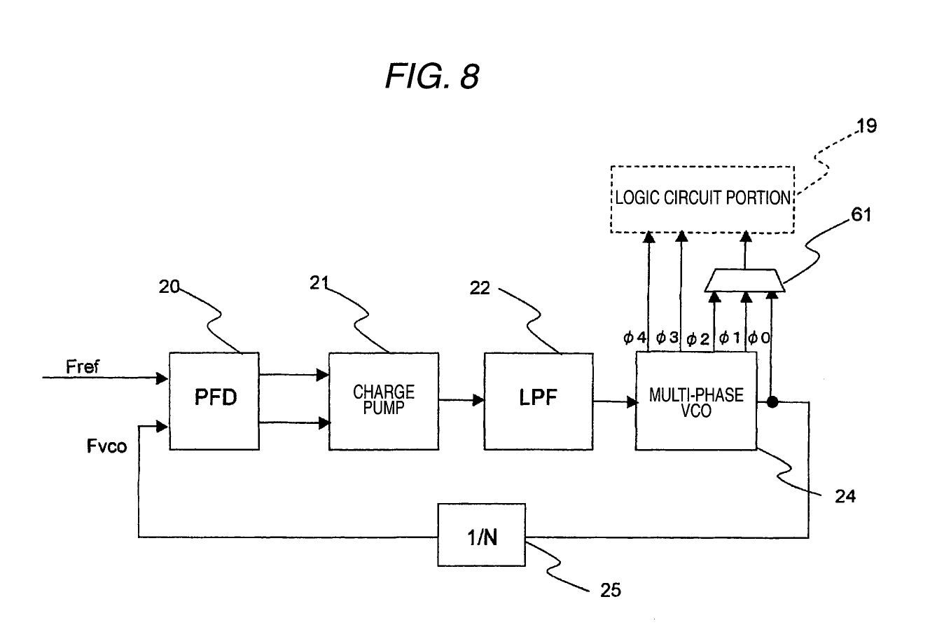

FIG. 8 is a block diagram showing a multi-phase clock generation portion according to the fifth embodiment. In the figure, constituent elements identical to those of the first embodiment are referred to by the common symbols, with explanation thereof being omitted.

The multi-phase clock generation portion shown in FIG. 8 is provided with a selector 61 between a multi-phase VCO 24 and a logic circuit portion 19. The selector 61 selects the clocks φ0, φ1, φ2 having different phases inputted from the multi-phase VCO 24 and outputs the selected clocks to the logic circuit portion 19.

According to the semiconductor integrated circuit of the fifth embodiment, as clocks selected by the selector 61, since a plurality of clocks are set so long as the margin of the set up error and the hold error does not become zero, clocks can be selected easily and the fine adjustment can be made after the completion of the timing adjustment and the distribution of a peak power level.

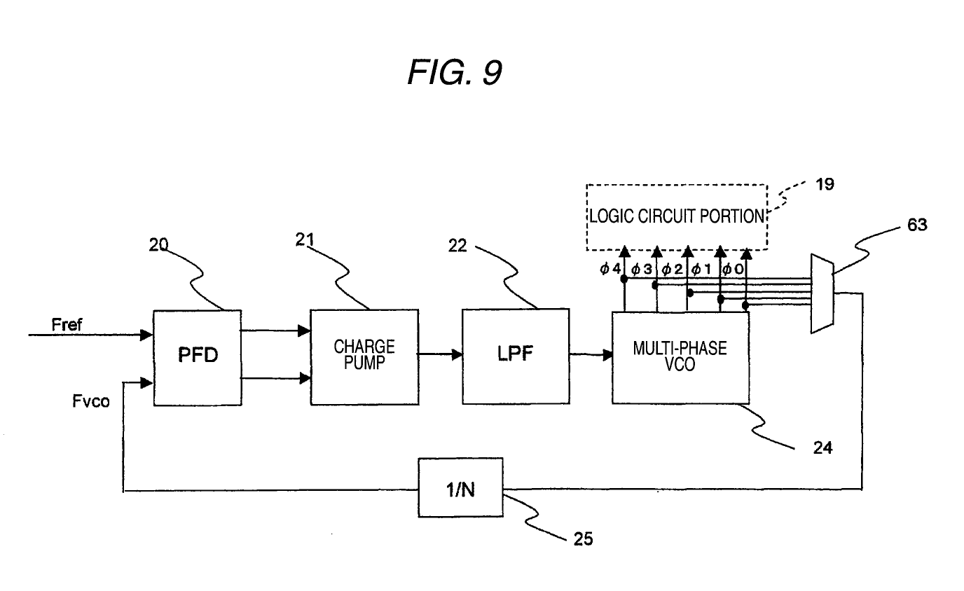

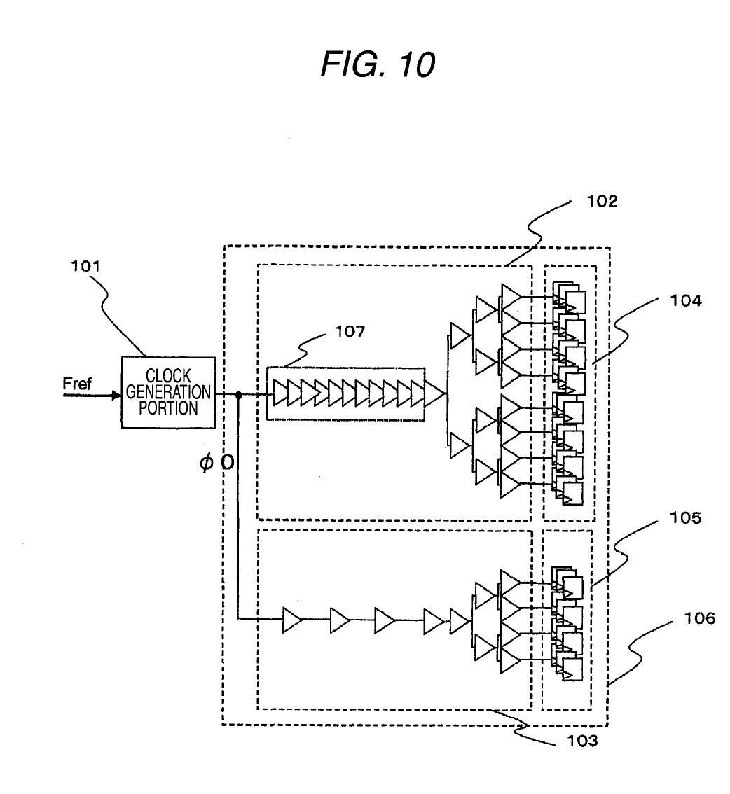

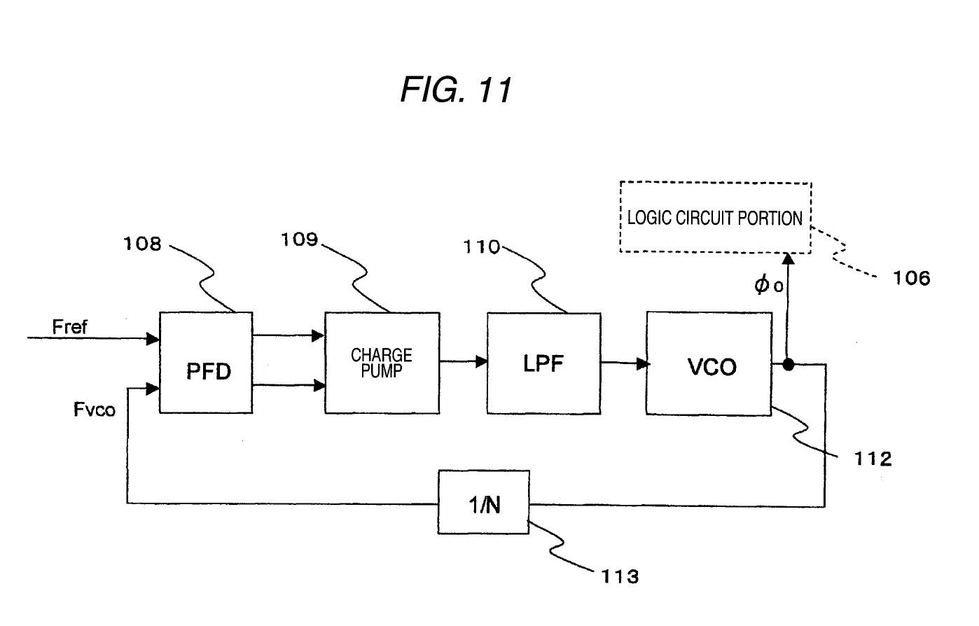

FIG. 9 is a block diagram showing a multi-phase clock generation portion according to the sixth embodiment. In the figure, constituent elements identical to those of the first embodiment are referred to by the common symbols, with explanation thereof being omitted.

The multi-phase clock generation portion shown in FIG. 9 is provided with a selector 63 between a multi-phase VCO 24 and a frequency dividing circuit (1/N) 25. The selector 63 selects the clocks φ0-φ4 having different phases inputted from the multi-phase VCO 24 and outputs the selected clocks to the frequency dividing circuit (1/N) 25.

According to the semiconductor integrated circuit of the sixth embodiment, since the selector 63 selects the clocks with different phases outputted from the multi-phase VCO 24 and feeds the selected clocks back to a phase/frequency detector (PFD) 20, the timings of the reference clock Fref inputted from an external IC and an internal clock Fvco can be relatively adjusted finely without changing the internal layout design.

The invention is not limited to the first to sixth embodiments. For example, in the second embodiment, although the frequency dividing circuit is provided in order to make the clock frequencies the same among the different kinds of clock domains having the relation of the integer number of times as to the clock frequencies, the clock frequencies may be made the same by providing a frequency multiplying circuit in place of the frequency dividing circuit.

The timing adjusting method and the semiconductor integrated circuit according to the invention are useful as the semiconductor integrated circuit etc. for adjusting timings among a plurality of the clock domains.

What is claimed is:

1. A clock timing adjusting method for adjusting a difference of clock timings among a plurality of clock domains in a semiconductor integrated circuit which includes a clock generation portion capable of supplying a plurality of clocks with different phases, a plurality of clock domains which is supplied with clocks from the clock generation portion and supplies the clocks thus supplied to corresponding flip-flop groups, respectively, and a logic circuit portion having the flip-flop groups, comprising:
a latency extracting step of extracting a latency of each of the plurality of clock domains;
a rough adjusting step of determining phases of clocks supplied to the clock domains among the plurality of clocks generated from the clock generation portion, based on the extracted latencies; and
a fine adjusting step of determining a number of clock buffers in order to adjust a latency difference of the plurality of clock domains which can not be adjusted by the clocks determined in the rough adjusting step.

2. The clock timing adjusting method according to claim 1, further comprising:
a clock timing changing step of shifting operating timing of the clocks of the phases determined in the rough adjusting step, at each of the clock domains, in accordance with an error state at a time where the clocks of the phases determined in the rough adjusting step are supplied to the plurality of clock domains.

3. A semiconductor integrated circuit, comprising:
a clock generation portion which is capable of supplying a plurality of clocks with different phases;
a plurality of clock domains which is supplied with clocks from the clock generation portion and supplies the clocks thus supplied to corresponding flip-flop groups, respectively; and
a logic circuit portion having the flip-flop groups, wherein
phases of the clocks supplied to the plurality of clock domains from the clock generation portion are determined based on latencies of the clock domains, and
at least one of the plurality of clock domains includes a clock buffer for adjusting a difference of the latencies of the plurality of clock domains which can not be adjusted by the clocks of the phases thus determined.

4. The semiconductor integrated circuit according to claim 3, wherein operating timing of the clocks of the phases thus determined is shifted at each of the clock domains in accordance with an error state at a time where the clocks of the phases thus determined are supplied to the plurality of clock domains.

5. The semiconductor integrated circuit according to claim 3, wherein the logic circuit portion includes frequency dividing circuits provided at pre-stages of the plurality of clock domains, respectively.

6. The semiconductor integrated circuit according to claim 3, wherein the clock generating portion includes a selector which selects and outputs one of the plurality of clocks with different phases.

7. The semiconductor integrated circuit according to claim 3, wherein the clock generating portion includes a selector which selects one of the plurality of clocks with different phases and feeds the selected one clock back into the clock generating portion.
